(19) United States
(12) Patent Application Publication
(10) Pub. No.: US 2007/0164819 A1
(43) Pub. Date: Jul. 19, 2007

(54) Amplifier

(76) Inventors: Junetsu Urata, Kodaira-shi (JP); Naoki Onishi, Chitose-shi (JP); Masaki Suto, Kodaira-shi (JP); Hironori Yokoyama, Kodaira-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/593,720

(22) PCT Filed: Mar. 24, 2005
(86) PCT No.: PCT/JP05/06210

§ 371 Date: Feb. 8, 2007

(30) Foreign Application Priority Data
Mar. 26, 2004 (JP) 2004-090892
Mar. 26, 2004 (JP) 2004-090843

(51) Int. Cl. H03F 3/68

(52) U.S. Cl. 330/124 R

(57) ABSTRACT

With an amplifier configured by including Doherty-type amplifier sections 21 to 25, the area of the circuits is reduced so that the size reduction is achieved. Moreover, the properties of the Doherty-type amplifier sections (Doherty properties) are stabilized against any environmental change of humidity and temperature. As an example, the permittivity of a substrate 3 configuring one or more of quarter wavelength lines 23 and/or 24 included in the Doherty-type amplifier sections 21 to 25 is increased compared with the permittivity of a substrate 2 in a close range. As another example, a line portion forming an output circuit of a carrier amplifier in the Doherty-type amplifier sections is configured by using a substrate material being physically stable against either or both of any change observed in the humidity and the temperature.

### TECHNICAL FIELD

The present invention relates to, for example, an amplifier for use by a base station device or others configuring a mobile communications system exemplified by a portable phone system or a personal handy phone system (PHS: Personal Handy phone System) and, more specifically, to a technology of downsizing a high-frequency power amplifier or others equipped with a Doherty-type amplifier for the aim of increasing the device efficiency.

The present invention also relates to an amplifier for use by such a base station device or others and, more specifically, to a technology of stabilizing the Doherty properties in a high-frequency power amplifier equipped with a Doherty-type amplifier for the aim of increasing the device efficiency.

### BACKGROUND ART

In recent years, in the wireless communications field, as is typified by a portable terminal device of a portable phone system or others, there has been a demand for downsizing the device. Such a demand for downsizing of the device similarly exists also for a base station device or others, and together therewith, there exits a demand for increasing the efficiency of a power amplifier that greatly influences the entire power consumption. Especially with the base station device, a high-frequency amplifier is often disposed in the vicinity of an antenna for the purpose of decreasing the cable loss between the high-frequency amplifier and the antenna. This is the reason why the high-frequency amplifier is strongly required to be smaller in size and better in efficiency.

Generally, the high-frequency power amplifier using a semiconductor element is increased in efficiency as the output increases, and the efficiency reaches its maximum in a close range of the saturation output. The level of the saturation output is dependent on the size of the semiconductor element in use. In consideration thereof, for the aim of increasing the efficiency with the low output, if a small-sized semiconductor element is used and the resulting amplifier has the low level of saturation output, the resulting output will not be enough as required for the time of high output. Conversely, if a large-sized semiconductor element is used and the resulting amplifier has highly-efficient at the time of high output, the efficiency is reduced when the output is low.

As such, it is considerably difficult to operate, with a high degree of efficiency, a single piece of amplifier at the time of both high and low outputs.

In order to solve such a problem, a so-called Doherty-type amplifier is developed.

FIG. 5 shows an exemplary standard configuration of a Doherty-type amplifier.

The Doherty-type amplifier of this example is configured to include a power splitter 81 that is disposed between an input terminal 71 and an output terminal 72 to split an input signal coming from the input terminal 71 into two, and two signal processing systems to process, respectively, the signals as a result of splitting. One of the signal processing systems includes a quarter wavelength line 83 connected in series to a carrier amplifier 82, which is configured as an amplifier biased to any of Classes A, AB, and B. The other signal processing system includes a quarter wavelength line 84 connected in series to a peak amplifier 85, which is configured as an amplifier biased to either Class B or C.

An exemplary operation to be operated by the Doherty-type amplifier of this example is shown.

When a high-frequency signal provided to the input terminal 71 is low in input power, the carrier amplifier 82 is biased to Class A, AB, or B, and outputs an amplifier signal by executing the amplifier operation irrespective of the input level of the input signal. On the other hand, the peak amplifier 85 is biased to either Class B or C, and when the instantaneous input power is low in level, the peak amplifier 85 is in the off state. The direct power consumption of the peak amplifier 85 is zero (0) or sufficiently small, and the efficiency as a Doherty-type amplifier is also high.

Moreover, when the instantaneous input power is sufficiently high in level, the peak amplifier 85 is turned into the on state, and the input signal directed to the peak amplifier 85 is amplified so that an output signal is generated. Thereafter, the output power from the carrier amplifier 82 is combined together with the output power from the peak amplifier 85 for output from the output terminal 72, and as a result thereby, configured is an amplifier having the large saturation power.

Note here that the Doherty-type amplifier is derived as a circuit being a combination result of an amplifier simply biased to Class A, AB, or B (the carrier amplifier 82), and an amplifier biased to Class B or C (the peak amplifier 85). In addition thereto, the amplifier is configured to implement the higher efficiency to a further degree by changing the dummy load impedance of the carrier amplifier 82 based on the function of the quarter wavelength line 83 provided on the output side of the carrier amplifier 82.

Patent Document 1

JP-A-2001-244751

The problem is that the Doherty-type amplifier is higher in efficiency compared with a case of solely using such a high-output amplifier as above with the high saturation output, but because the circuit is complicated in configuration, the circuit area is increased.

Here, in order to solve such a problem, for example, a possibility is a technique of configuring a device substrate entirely using a material high in permittivity. However, the material having a high permittivity is generally expensive. Especially if with a ceramics substrate material of high permittivity, it easily causes cracking, and it is thus very difficult to manufacture the entire device by a single piece of substrate. What is more, compared with a low-permittivity substrate, the high-permittivity substrate requires the high pattern accuracy. Therefore, increasing the permittivity of every substrate in the device actually makes a contribution to the size reduction of the device, but this problematically results in not only a cost increase of the substrate material but also an enormous cost increase due to the reduction of a manufacturing yield, the accuracy control over the substrate, or others.

Furthermore, the Doherty-type amplifier is higher in efficiency compared with a case of solely using such a high-output amplifier as above with the high saturation output, but the circuit configuration is complicated, and influence is exerted by any physical change observed in the circuit configuration caused by various reasons. For example, this increases, to the level not negligible, the change of electric length caused by fluctuations of the permittivity as a result of the substrate taking up moisture, or the dimension change caused by shrinkage of the substrate affected by the temperature. Such a change observed in the electrical properties of the substrates becomes a cause of hindering the Doherty-type amplifier from operating as is supposed to in consideration of the properties thereof.

Herein, to solve such problems, for example, there is a possible technique of configuring a Doherty-type amplifier entirely by a highly-stable substrate material. However, the stable material typified by a ceramic substrate or others is expensive, and resultantly increases the cost of the device. Moreover, if with a ceramic substrate, there is a possibility of cracking, and it is thus difficult to make a single substrate to cover a large area.

The present invention is proposed in consideration of such conventional circumstances as above, and an object thereof is to provide an amplifier that can achieve size reduction in the configuration of including a Doherty-type amplifier by reducing the circuit area.

The present invention is proposed in consideration of such conventional circumstances as above, and an object thereof is to provide an amplifier that can stabilize the properties of a Doherty-type amplifier (Doherty properties) in the configuration of including a Doherty-type amplifier.

### DISCLOSURE OF THE INVENTION

In order to achieve the above object, the amplifier of the present invention takes the following configuration in the configuration of including a Doherty-type amplifier section (Doherty-type amplifier).

That is, the permittivity of a substrate configuring one or more quarter wavelength lines in the Doherty-type amplifier section is increased compared with the permittivity of a substrate(s) in a close range.

Accordingly, by configuring one or more quarter wavelength lines in the Doherty-type amplifier section using a substrate having a relatively high permittivity, in the configuration of including the Doherty-type amplifier section, the circuit area is reduced for one or more quarter wavelength lines, for example. Therefore, the circuit area can be reduced in the amplifier so that the size reduction can be achieved.

Herein, the configuration of the Doherty-type amplifier section may vary in type, and as an example, such a configuration as shown in FIG. 5 is a possibility.

Further, the substrate or the permittivity of the substrate may vary in type or value.

Still further, the amplifier may vary in configuration, and an exemplary configuration includes a Doherty-type amplifier section, a high-frequency amplifier section (high-frequency amplifier), and an isolator section (isolator).

The amplifier of the present invention takes the following configuration in the configuration of including a Doherty-type amplifier section (Doherty-type amplifier).

That is, the permittivity of a substrate configuring the Doherty-type amplifier section is made higher than the permittivity of the substrate(s) in a close range.

Accordingly, by configuring the Doherty-type amplifier section using a substrate having a relatively high permittivity, in the configuration of including the Doherty-type amplifier section, the circuit area is reduced for components being dependent on the frequency of the Doherty-type amplifier section, for example. Therefore, the circuit area can be reduced in the amplifier so that the size reduction can be achieved.

Herein, the configuration of the Doherty-type amplifier section may vary in type, and as an example, such a configuration as shown in FIG. 5 is a possibility.

Further, the substrate or the permittivity of the substrate may vary in type or value.

Still further, the amplifier may vary in configuration, and an exemplary configuration includes a Doherty-type amplifier section, a high-frequency amplifier section (high-frequency amplifier), and an isolator section (isolator).

In order to achieve the above object, the amplifier of the present invention takes the following configuration in the configuration of including a Doherty-type amplifier section (Doherty-type amplifier).

That is, a line portion forming an output circuit of a carrier amplifier included in the Doherty-type amplifier section is configured using a substrate material that is physically stable against either or both of any change observed in the humidity and the temperature.

Accordingly, by using a physically-stable substrate to configure the output circuit of the carrier amplifier that is a component of the Doherty-type amplifier section, against any environmental change of humidity or temperature, for example, the properties of the Doherty-type amplifier section (Doherty properties) can be stabilized.

As an exemplary configuration, in the amplifier configured by including the Doherty-type amplifier section, the configuration can use a substrate material being physically stable, compared with portions in a close range (or other portions), against either or both of any change observed in the humidity and the temperature for a substrate material of the line portion forming an output circuit of a carrier amplifier included in the Doherty-type amplifier section.

Herein, the configuration of the Doherty-type amplifier section may vary in type, and as an example, such a configuration as shown in FIG. 5 is a possibility.

Further, the substrate may vary in type.

Still further, the physically-stable substrate material may vary in kind, and a possible exemplary material is the one showing a sufficiently small change of the electric length as a result of fluctuations of the permittivity caused by moisture absorption, or the one showing a sufficiently small change of dimension as a result of shrinkage of the substrate affected by the temperature.

Still further, used as the carrier amplifier is an amplifier that operates in such a manner as to amplify a signal as an amplification target irrespective of the level of the signal. The Doherty-type amplifier section is equipped with, for example, a carrier amplifier that is always put in operation from when a signal as an amplification target is relatively low in level, and a peak amplifier that is put in operation only when the signal as an amplification target is relatively high in level.

The amplifier may vary in configuration, and an exemplary configuration includes a Doherty-type amplifier section, a high-frequency amplifier section (high-frequency amplifier) provided in the stage preceding to the Doherty-type amplifier section (input side), and an isolator section (isolator) provided in the stage subsequent to the Doherty-type amplifier section (output side).

The amplifier of the present invention takes the following configuration in the configuration of including a Doherty-type amplifier section (Doherty-type amplifier).

That is, a line portion forming an input circuit of a peak amplifier included in the Doherty-type amplifier section is configured using a substrate material that is physically stable against either or both of any change observed in the humidity and the temperature.

Accordingly, by using a physically-stable substrate to configure the input circuit of the peak amplifier that is a component of the Doherty-type amplifier section, against any environmental change of humidity or temperature, for example, the properties of the Doherty-type amplifier section (Doherty properties) can be stabilized.

As an exemplary configuration, in the amplifier configured by including the Doherty-type amplifier section, the configuration can use a substrate material being physically stable, compared with portions in a close range (or other portions), against either or both of any change observed in the humidity or the temperature for a substrate material of a line portion forming an input circuit of a peak amplifier included in the Doherty-type amplifier section.

Herein, the configuration of the Doherty-type amplifier section may vary in type, and as an example, such a configuration as shown in FIG. 5 is a possibility.

Further, the substrate may vary in type.

Still further, the physically-stable substrate material may vary in kind, and a possible exemplary material is the one showing a sufficiently small change of the electric length as a result of fluctuations of the permittivity caused by moisture absorption, or the one showing a sufficiently small change of the dimension as a result of shrinkage of the substrate affected by the temperature.

Still further, used as the peak amplifier is an amplifier that operates in such a manner as to amplify a signal as an amplification target when the level of the signal reaches its peak. The Doherty-type amplifier section is equipped with, for example, a carrier amplifier that is always put in operation from when a signal as an amplification target is relatively low in level, and a peak amplifier that is put in operation only when the signal as an amplification target is relatively high in level.

The amplifier may vary in configuration, and an exemplary configuration includes a Doherty-type amplifier section, a high-frequency amplifier section (high-frequency amplifier) provided in the stage preceding to the Doherty-type amplifier section (input side), and an isolator section (isolator) provided in the stage subsequent to the Doherty-type amplifier section (output side).

The amplifier of the present invention takes the following configuration in the configuration of including a Doherty-type amplifier section (Doherty-type amplifier).

That is, a line portion forming a combination circuit that combines an output from a carrier amplifier included in the Doherty-type amplifier section with an output from a peak amplifier is configured using a substrate material that is physically stable against either or both of any change observed in the humidity and the temperature.

Accordingly, by using a physically-stable substrate to configure the combination circuit that is a component of the Doherty-type amplifier section, against any environmental change of humidity or temperature, for example, the properties of the Doherty-type amplifier section (Doherty properties) can be stabilized.

As an exemplary configuration, in the amplifier configured by including the Doherty-type amplifier section, the configuration can use a substrate material being physically stable, compared with portions in a close range (or other portions), against either or both of any change observed in the humidity and the temperature for a substrate material of a line portion forming a combination circuit that combines an output from a carrier amplifier included in the Doherty-type amplifier section with an output from a peak amplifier.

The amplifier of the present invention takes the following configuration in the configuration of including a Doherty-type amplifier section (Doherty-type amplifier).

That is, a line portion forming an output circuit of a peak amplifier included in the Doherty-type amplifier section is configured using a substrate material that is physically stable against either or both of any change observed in the humidity and the temperature.

Accordingly, by using a physically-stable substrate to configure the output circuit of the peak amplifier that is a component of the Doherty-type amplifier section, against any environmental change of humidity or temperature, for example, the properties of the Doherty-type amplifier section (Doherty properties) can be stabilized.

As an exemplary configuration, in the amplifier configured by including the Doherty-type amplifier section, the configuration can use a substrate material being physically stable, compared with portions in a close range (or other portions), against either or both of any change observed in the humidity and the temperature for a substrate material of a line portion forming an output circuit of a peak amplifier included in the Doherty-type amplifier section.

The amplifier of the present invention takes the following configuration in the configuration of including a Doherty-type amplifier section (Doherty-type amplifier).

That is, a line portion forming an input circuit of a carrier amplifier included in the Doherty-type amplifier section is configured using a substrate material that is physically stable against either or both of any change observed in the humidity and the temperature.

Accordingly, by using a physically-stable substrate to configure the input circuit of the carrier amplifier that is a component of the Doherty-type amplifier section, against any environmental change of humidity or temperature, for example, the properties of the Doherty-type amplifier section (Doherty properties) can be stabilized.

As an exemplary configuration, in the amplifier configured by including the Doherty-type amplifier section, the configuration can use a substrate material being physically stable, compared with portions in a close range (or other portions), against either or both of any change observed in the humidity and the temperature for a substrate material of a line portion forming an input circuit of a carrier amplifier included in the Doherty-type amplifier section.

The amplifier of the present invention takes the following configuration in the configuration of including a Doherty-type amplifier section (Doherty-type amplifier).

That is, the permittivity of a substrate configuring partially or entirely the Doherty-type amplifier section is increased compared with the permittivity of substrate(s) in a close range, and a line portion forming a part of the Doherty-type amplifier section is configured using a substrate material being physically stable against either or both of any change observed in the humidity and the temperature.

Accordingly, in the configuration of including the Doherty-type amplifier section, the amplifier can be reduced in circuit area so that the size reduction can be achieved, and against any environmental change of humidity or temperature, for example, the properties of the Doherty-type amplification section (Doherty properties) can be stabilized.

### BRIEF DESCRIPTION OF THE DRAWINGS

FIG. 1 is a diagram showing an exemplary configuration of a highly-efficient high-frequency amplifier device in an example of the present invention.

FIG. 2 is a diagram showing an exemplary configuration of a substrate of a highly-efficient high-frequency amplifier device in an example of the present invention.

FIG. 3 is a diagram showing an exemplary configuration of a highly-efficient high-frequency amplifier device in an example of the present invention.

FIG. 4 is a diagram showing an exemplary configuration of a Doherty-type amplifier in an example of the present invention.

FIG. 5 is a diagram showing an exemplary configuration of a Doherty-type amplifier.

### BEST MODE FOR CARRYING OUT THE INVENTION

Examples of the present invention are described by referring to the accompanying drawings.

First of all, described are first to sixth examples.

In these examples, exemplified is a case in which the present invention is applied to an amplifier device (a highly-efficient high-frequency amplifier device) that implements a high degree of efficiency through amplification of high-frequency signals such as radio frequency (RF: Radio Frequency), for example. The resulting amplifier device is used in communications devices exemplified by base station devices.

More specifically, to configure a high-frequency amplifier device including a Doherty-type amplifier, substrates varying in permittivity are used for the substrate configuration of the device, and any components needed to form the Doherty-type amplifier, e.g., a quarter wavelength line, a matching circuit, a bias circuit, a splitter circuit, a combination circuit, and others, are provided by a substrate section having a high permittivity. As an exemplary possible configuration, a substrate for at least one or more quarter wavelength line portions in the Doherty-type amplifier is made to have a higher permittivity than any other substrate in a close range, or a substrate for the portion of the Doherty-type amplifier is made to have a higher permittivity than any other substrate in a close range. Such a configuration enables to suppress the increase of the area occupied by the circuits, which is often caused by the use of the Doherty-type amplifier so that a small-sized highly-efficient high-frequency amplifier device can be realized.

### FIRST EXAMPLE

Described now is a highly-efficient high-frequency amplifier device in the first example of the present invention.

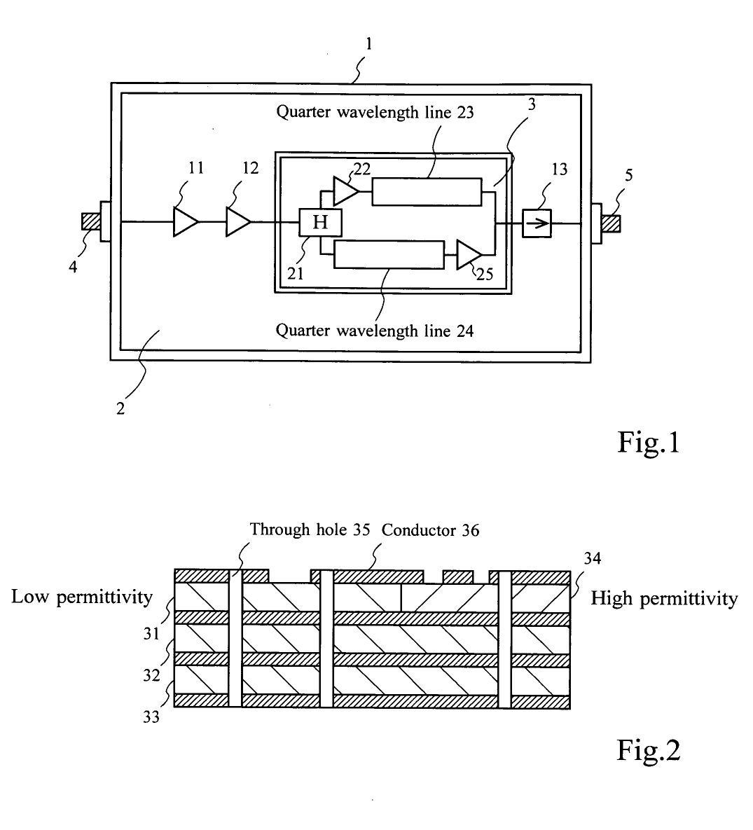

FIG. 1 shows an exemplary configuration of a highly-efficient high-frequency amplifier device of this example.

The highly-efficient high-frequency amplifier device of this example is provided with, in a case 1, a substrate having a low permittivity (low-permittivity substrate) 2, and a substrate having a high permittivity (high-permittivity substrate) 3. The case 1 is equipped with a connector for inputting a high-frequency signal (high-frequency input connector) 4, and a connector for outputting the high-frequency signal (high-frequency output connector) 5. The permittivity of the low-permittivity substrate 2 is lower than that of the high-permittivity substrate 3, that is, the permittivity of the high-permittivity substrate 3 is higher than the permittivity of the low-permittivity substrate 2.

Herein, used as the low-permittivity substrate 2 is an FR-4 substrate having a relativepermittivity of 4.3, for example, and used as the high-permittivity substrate 3 is a ceramic substrate having a relativepermittivity of 9.8.

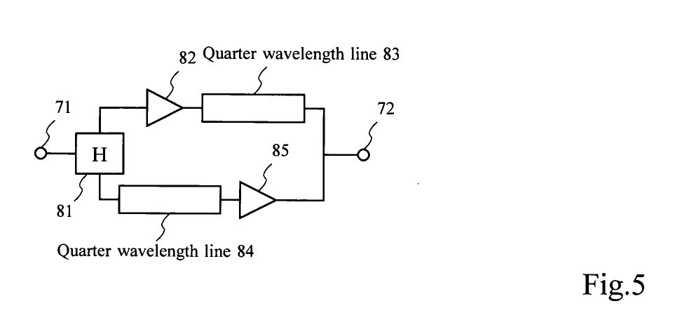

The high-permittivity substrate 3 is provided with a Doherty-type amplifier configured by components similar to those shown in FIG. 5, for example. The Doherty-type amplifier of this example is provided with a power splitter 21, and for one of the resulting splitter signals, provided are a carrier amplifier 22 configured as an amplifier that is biased to any one of Classes A, AB, and B, and a quarter wavelength line 23. For the other resulting splitter signal, provided are a quarter wavelength line 24, and a peak amplifier 25 configured as an amplifier that is biased to either Class B or C.

The low-permittivity substrate 2 includes two high-frequency amplifiers 11 and 12 that are connected in series for use as a drive stage between the high-frequency input connector 4 and the input end of the Doherty-type amplifier, and includes an isolator 13 between the output end of the Doherty-type amplifier and the high-frequency output connector 5.

Note that, in this example, although the low-permittivity substrate 2 is incorporated thereon with a control circuit, a power supply circuit, and others, those are not shown nor described in detail. Moreover, in this example, any high-frequency connection among various types of substrates is also not shown nor described in detail. It is possible to realize the connection with ease by any known technique such as a technique of using an element causing a small loss at a required frequency, e.g., a technique of establishing a connection via a chip such as chip capacitor with thought given to the frequency characteristics, or a technique of using a gold ribbon, wire bonding, or others.

Herein, with the Doherty-type amplifier of this example, the components 21 to 25 include the so-called quarter wavelength lines 23 and 24 as transmission lines dependent on the frequency, in other words, transmission lines dependent on the electric length. Even if some design attempts are made to change the transmission lines in layout, there are thus limitations on reduction of the occupied area.

In consideration thereof, in this example, the substrate for a portion of the Doherty-type amplifier is the high-permittivity substrate 3 having a relatively high permittivity, and the substrate for other portions is the low-permittivity substrate 2 having a relatively low permittivity. In the configuration of this example, compared with a case of using the low-permittivity substrate 2 for all of the circuits 11 to 13, and 21 to 25 in the case 1, for example, the configuration can be completed with almost a half of the area. More specifically, by converting the permittivity to the electric length, the ratio of the area will be (4.3/9.8×100)=43.9 percents (%). As such, the highly-efficient high-frequency amplifier can be reduced in size.

As described above, with the highly-efficient high-frequency amplifier device of this example, in the configuration of including at least one or more of the high-frequency amplifiers 11 and/or 12 and the Doherty-type amplifier, circuits in one or more of the high-frequency amplifiers 11 and/or 12 are configured by a substrate material having a low permittivity (the low-permittivity substrate 2), and the circuits of the Doherty-type amplifier are configured by a substrate material having a higher permittivity (the high-permittivity substrate 3) compared with the substrate material (the low-permittivity substrate 2) used for one or more of the high-frequency amplifiers 11 and/or 12, and the configuration results are combined together. With such a configuration, realized is the high-frequency amplifier device to be higher in efficiency and smaller in size.

To be more specific, in this example, in the amplifier (in this example, the highly-efficient high-frequency amplifier device) configured by including the Doherty-type amplifier sections (Doherty-type amplifiers) 21 to 25, the substrate 3 configuring one or more of the quarter wavelength lines 23 and/or 24 included in the Doherty-type amplifier sections 21 to 25 is increased in permittivity compared with the permittivity of the substrate(s) 2 in a close range. Moreover, in this example, further, the permittivity of the substrate 3 configuring entirely the Doherty-type amplifier sections 22 to 25 is increased compared with the permittivity of the substrate(s) 2 in a close range.

Accordingly, with the highly-efficient high-frequency amplifier device of this example, in the high-frequency amplifier device using the Doherty-type amplifier for the aim of increasing the efficiency, the device can be reduced in size by using the high-permittivity substrate 3 to the circuit portions occupying the larger area such as the circuits configuring the Doherty-type amplifier. For example, compared with such a case that every circuit configuring the device is realized by the high-permittivity substrate, the resulting amplifier device can have a high degree of efficiency with lower cost and less manufacturing efforts.

As such, with the highly-efficient high-frequency amplifier device of this example, it is possible to suppress the increase of the area occupied by the circuits of the high-frequency amplifier device, which is often caused by the use of the Doherty-type amplifier so that a small-sized highly-efficient high-frequency amplifier device can be realized.

Herein, the material of the low-permittivity substrate 2 and the material of the high-permittivity substrate 3 may both vary in type.

### SECOND EXAMPLE

Described now is a highly-efficient high-frequency amplifier device in the second example of the present invention.

The highly-efficient high-frequency amplifier device of this example takes the form that the low-permittivity substrate 2 and the high-permittivity substrate 3 are attached together for use as a single piece of substrate in such a device configuration as shown in FIG. 1, for example. Such a form implements the size reduction of the highly-efficient high-frequency amplifier device.

FIG. 2 shows an exemplary configuration of a substrate of the highly-efficient high-frequency amplifier device in this example.

More specifically, shown is the cross section of an exemplary composite substrate that is derived by attaching together low-permittivity substrates 31, 32, and 33 (corresponding to the low-permittivity substrate 2) and a high-permittivity substrate 34 (corresponding to the high-permittivity substrate 3). The drawing is showing an exemplary through hole 35 and an exemplary conductor 36.

As described above, with the highly-efficient high-frequency amplifier device of this example, in the configuration of including at least one or more of the high-frequency amplifiers 11 and/or 12, the Doherty-type amplifier, and a single piece of substrate derived by attaching together a plurality of substrate materials varying in permittivity, the Doherty-type amplifier is configured to come to the high-permittivity substrate portion of the substrate of the attachment result. This favorably realizes the high-frequency amplifier device to be higher in efficiency and smaller in size.

### THIRD EXAMPLE

Described now is a highly-efficient high-frequency amplifier device in the third example of the present invention.

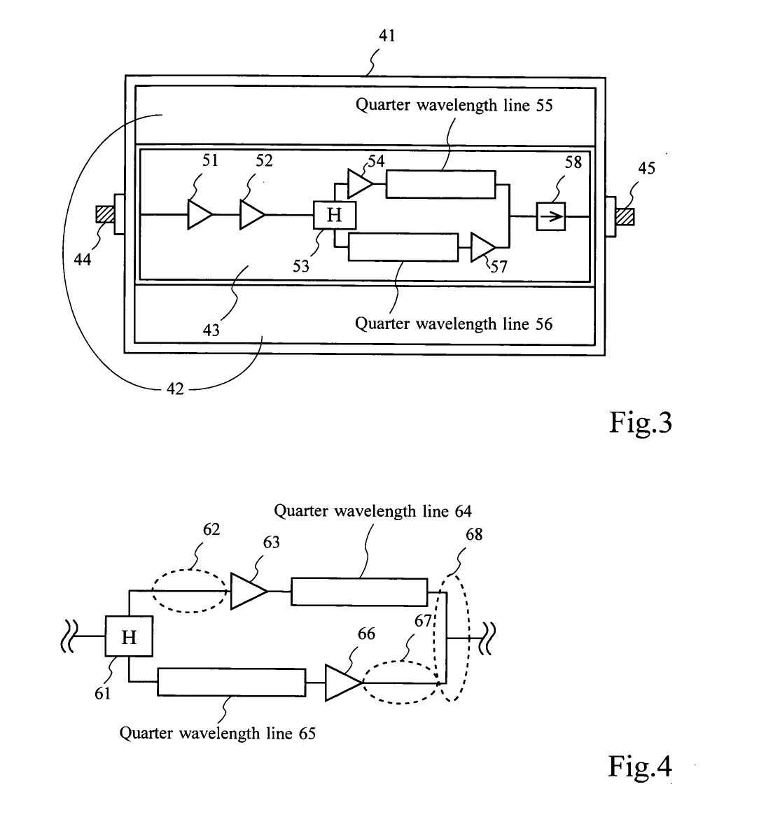

FIG. 3 shows an exemplary configuration of the highly-efficient high-frequency amplifier device of this example.

In the highly-efficient high-frequency amplifier device of this example, a high-permittivity substrate 43 is provided with not only the Doherty-type amplifier but also two high-frequency amplifiers 51 and 52.

More specifically, in a case 41 including a high-frequency input connector 44 and a high-frequency output connector 45, a low-permittivity substrate 42 and a high-permittivity substrate 43 are included. The high-permittivity substrate 43 includes a power splitter 53, a carrier amplifier 54, two quarter wavelength lines 55 and 56, and a peak amplifier 57, all of which configure the Doherty-type amplifier. Therein, the two high-frequency amplifiers 51 and 52 are included in the stage preceding to the Doherty-type amplifier, and the isolator 58 is included in the state subsequent to the Doherty-type amplifier.

Moreover, in this example, the low-permittivity substrate 42 is configured by being incorporated thereon with a control circuit, a power supply circuit, and others, and the high-permittivity substrate 43 is configured by being incorporated thereon with any other high-frequency signal processing portions.

Note here that, with the highly-efficient high-frequency amplifier device of this example, schematically, the configuration of the Doherty-type amplifier, the configuration of the circuit elements 41 to 45 and 51 to 58, and the entire configuration are similar to those in the highly-efficient high-frequency amplifier device shown in FIG. 1.

Herein, because the Doherty-type amplifier requires the components dependent on the frequency, it is considered effective to configure the circuits on the high-permittivity substrate 43. For other high-frequency signal processing portions (for example, the high-frequency amplifiers 51 and 52, and the isolator 58 in this example) often include a matching circuit, a bias circuit, or others by pattern formation, and by using the high-permittivity substrate 43, the area occupied thereby can be effectively reduced. In this manner, in this example, the highly-efficient high-frequency amplifier device can be reduced in size to a further extent.

As described in the foregoing, with the highly-efficient high-frequency amplifier device of this example, in the configuration of including at least one or more of the high-frequency amplifiers 51 and/or 52, the Doherty-type amplifier, and circuits of a power supply circuit, a control circuit, or others accompanying one or more of these amplifiers, the high-frequency circuit portions including one or more of the high-frequency amplifiers 51 and/or 52 and the Doherty-type amplifier are configured by a substrate material having a high permittivity (the high-permittivity substrate 43), and the accompanying power supply circuit, control circuit, or others are configured by a substrate material having a low permittivity (the low-permittivity substrate 42) such as glass epoxy having a good cost performance. The configuration results a recombined together for use. With such a configuration, the high-frequency amplifier device can be increased in efficiency and reduced in size.

More specifically, in this example, in the amplifier (in this example, the highly-efficient high-frequency amplifier device) configured by including the Doherty-type amplifier sections (Doherty-type amplifiers) 53 to 57, the substrate 43 configuring one or more of the quarter wavelength lines 55 and/or 56 in the Doherty-type amplifier sections 53 to 57 is increased in permittivity compared with the permittivity of the substrate 42 in a close range. Moreover, in this example, further, the permittivity of the substrate 43 configuring entirely the Doherty-type amplifier sections 53 to 57 is increased compared with the permittivity of the substrate 42 in a close range.

### FOURTH EXAMPLE

Described now is a highly-efficient high-frequency amplifier device in the fourth example of the present invention.

With the highly-efficient high-frequency amplifier device of this example, the device configuration exemplarily shown in FIG. 3 takes the form that the low-permittivity substrate 42 and the high-permittivity substrate 43 are attached together for use as a single piece of substrate. More specifically, for example, the substrate is configured similarly to the one shown in FIG. 2, for example. With such a form, the highly-efficient high-frequency amplifier device can be reduced in size.

As described in the foregoing, in the highly-efficient high-frequency amplifier device of this example, in the configuration of including at least one or more of the high-frequency amplifiers 51 and/or 52, the Doherty-type amplifier, circuits of a power supply circuit, a control circuit, or others accompanying one or more of these amplifiers, and a single piece of substrate formed by attaching together a plurality of substrate materials varying in permittivity, the high-frequency circuit portions including one or more of the high-frequency amplifiers 51 and/or 52 and the Doherty-type amplifier are configured by a substrate material having a high permittivity (the high-permittivity substrate 43). With such a configuration, the high-frequency amplifier device can be increased in efficiency and reduced in size.

### FIFTH EXAMPLE

Described now is a highly-efficient high-frequency amplifier device in the fifth example of the present invention.

With the highly-efficient high-frequency amplifier device of this example, the portions covering up to the power splitter circuit of the Doherty-type amplifier are configured by the low-permittivity substrate, and in the example of FIG. 1, for example, components configured by the low-permittivity substrate 2 are the two high-frequency amplifiers 11 and 12 for use as a drive stage, the power splitter 21, and the quarter wavelength line 24. With the highly-efficient high-frequency amplifier device of this example, the power combination circuit portion of the Doherty-type amplifier is configured by the high-permittivity substrate, and in the example of FIG. 1, for example, the combination circuit portion including the quarter wavelength line 23 (for example, the carrier amplifier 22, the quarter wavelength line 23, and the peak amplifier 25) is configured by the high-permittivity substrate 3.

As described in the foregoing, in the highly-efficient high-frequency amplifier device of this example, in the configuration of including at least one or more of the high-frequency amplifiers 11 and/or 12 and the Doherty-type amplifier, the substrate material having a low permittivity (the low-permittivity substrate 2) is used to configure the power splitter circuit of one or more of the high-frequency amplifiers 11 and/or 12 and the Doherty-type amplifier, and the combination circuit portion of the Doherty-type amplifier is configured by the substrate material having a higher permittivity (the high-permittivity substrate 3) compared with the substrate material (the low-permittivity substrate 2) for use to the power splitter circuit of one or more of the high-frequency amplifiers 11 and/or 12 and the Doherty-type amplifier. The configuration results are combined together for use. Such a configuration enables the high-frequency amplifier device to be increased in efficiency and reduced in size.

More specifically, in this example, in the amplifier (in this example, the highly-efficient high-frequency amplifier device) configured by including the Doherty-type amplifier sections (Doherty-type amplifiers) 21 to 25, the substrate 3 configuring one or more of the quarter wavelength lines 23 and/or 24 (the quarter wavelength line 23 in this example) included in the Doherty-type amplifier sections 21 to 25 is increased in permittivity compared with the permittivity of the substrate(s) 2 in a close range.

### SIXTH EXAMPLE

Described now is a highly-efficient high-frequency amplifier device in the sixth example of the present invention.

With the highly-efficient high-frequency amplifier device of the example, the device configuration exemplarily shown in the fifth example, for example, takes the form in which the low-permittivity substrate 2 and the high-permittivity substrate 3 are attached together for use as a single piece of substrate. More specifically, for example, the substrate is configured similarly to the one shown in FIG. 2. With such a configuration, the highly-efficient high-frequency amplifier device can be reduced in size.

As described in the foregoing, with the highly-efficient high-frequency amplifier device of this example, used is a single piece of substrate formed by attaching together the substrate material having a low permittivity (the low-permittivity substrate 2) configuring the power splitter circuits of the high-frequency amplifiers 11 and 12 and the Doherty-type amplifier to the substrate material having a high permittivity (the high-permittivity substrate 3) configuring the combination circuit portion of the Doherty-type amplifier. With such a configuration, the high-frequency amplifier device is increased in efficiency and reduced in size.

Here, in this example, shown is the configuration with some design attempt made to the substrate itself. Alternatively, by making some design attempt to the quarter wavelength line, for example, the effects similar to this example can be implemented (e.g., size reduction of the device). As a specific example, the quarter wavelength line may possibly take (1) the configuration in which a microstrip line is used for adjustment, (2) the configuration in which outer and inner conductors of a coaxial cable are exchanged, and (3) the configuration of using a triplate line.

Described next are seventh to eleventh examples.

In these examples, exemplified is a case in which the present invention is applied to a Doherty-type amplifier equipped to an amplifier device (a highly-efficient high-frequency amplifier device) that can realize a high degree of efficiency through amplification of high-frequency signals such as radio frequency (RF: Radio Frequency), for example. The amplifier device is used by communications devices such as base station devices.

More specifically, to configure a high-frequency amplifier device including a Doherty-type amplifier, as the substrate configuration of the device, the transmission lines of any arbitrary portion are configured by using a substrate being stable against the humidity, the temperature, and others, thereby reducing the degradation of properties caused by any change observed in the circumferential environment. As an exemplary configuration, a substrate for an input/output portion of a peak carrier is increased in resistance against any environmental change so that the resulting Doherty-type amplifier is realized to be resistant against environmental change, or a substrate for the Doherty-type amplifier may be made more stable against the humidity, the temperature, and others compared with the substrate(s) in a close range.

### SEVENTH EXAMPLE

Described now is a highly-efficient high-frequency amplifier device in the seventh example of the present invention.

FIG. 4 shows an exemplary configuration of a Doherty-type amplifier equipped in a highly-efficient high-frequency amplifier device of this example.

The Doherty-type amplifier of this example is equipped with a power splitter 61. For one of the resulting splitter signals, included are a carrier amplifier 63 that is configured as an amplifier biased to any of Classes A, AB, and B, and a quarter wavelength line 64. For the other splitter signal, included are a quarter wavelength line 65, and a peak amplifier 66 configured as an amplifier biased to either Class B or C.

FIG. 4 shows, as components of the Doherty-type amplifier of this example, an input circuit (e.g., input line) 62 for the carrier amplifier 63, an output circuit (e.g., output line) 67 for the peak amplifier 66, and a combination circuit 68 that combines an output from the carrier amplifier 63 with an output from the peak amplifier 66.

Herein, the Doherty-type amplifier is generally configured by a substrate material of glass epoxy, which is inexpensive and easily obtained. In this example, however, the portion of the output circuit 67 of the peak amplifier 66 is configured by a substrate material being stable. To be more specific, in this example, used as the substrate material for the portion of the output circuit 67 of the peak amplifier 66 is a substrate material such as ceramics, thereby implementing the Doherty-type amplifier leading to the properties being stable against any change observed in environmental requirements of humidity, temperature, and others. The resulting Doherty-type amplifier stable in Doherty properties as such is applied to the highly-efficient high-frequency amplifier device.

Moreover, in this example, the highly-stable substrate material such as ceramics is used to a necessary-minimum portion, thereby achieving the stable Doherty operation with the minimum cost increase.

Note here that, in this example, the high-frequency connection among various types of substrates is not shown nor described in detail. It is possible to realize the connection with ease by any known technique such as a technique of using an element causing a small loss at a required frequency, e.g., a technique of establishing a connection via a chip such as chip capacitor with thought given to the frequency characteristics, or a technique of using a gold ribbon, wire bonding, or others.

As described in the foregoing, with the highly-efficient high-frequency amplifier device of this example, in the configuration of including the Doherty-type amplifier, a substrate material that is physically stable against the humidity, the temperature, and others, is used for a high-frequency line portion forming the output circuit 67 of the peak amplifier 66 that is one of the components of the Doherty-type amplifier. This enables to reduce the degradation of the Doherty properties caused by any property change observed in the substrate material affected by the change of circumferential environment relating to the humidity, the temperature, and others. For example, the degradation of the characteristics can be minimized.

As such, with the highly-efficient high-frequency amplifier device of this example, in the configuration of including the Doherty-type amplifier sections (Doherty-type amplifiers) 61 to 68, the line portion forming the output circuit 67 of the peak amplifier 66 in the Doherty-type amplifier sections 61 to 68 is configured by using a substrate material being physically stable against any humidity change, any temperature change, or others.

Accordingly, with the highly-efficient high-frequency amplifier device of this example, in the configuration of using a Doherty-type amplifier for the purpose of increasing the efficiency, for example, it becomes possible to solve the instability of the circuits configuring the Doherty-type amplifier, and prevent the properties from being degraded as a result of any property change observed in the substrate as a result of the humidity, the temperature, and others so that the resulting amplifier device can be high in efficiency and less susceptible to the change of circumferential environment.

Alternatively, as another exemplary configuration, without restricting the portion for a stable substrate material to the portion of the output circuit 67 of the peak amplifier 66, further, the substrate material for a portion susceptible to the state of the substrate material may be replaced with the stable substrate material. With this being the case, the properties can be stabilized to a further extent.

As such, as the configuration of the substrate of the Doherty-type amplifier, a plurality of substrates can be variously combined, and various other configurations will do.

### EIGHTH EXAMPLE

Described now is a highly-efficient high-frequency amplifier device in the eighth example of the present invention.

In the highly-efficient high-frequency amplifier device of this example, in the configuration of including a Doherty-type amplifier, a substrate material that is physically stable against the humidity, the temperature, and others, is used for a high-frequency line portion forming the input circuit 62 of the carrier amplifier 63 that is one of the components of the Doherty-type amplifier.

This enables to reduce the degradation of the Doherty properties caused by any property change observed in the substrate material as a result of the change of circumferential environment relating to the humidity, the temperature, and others. For example, the degradation of the characteristics can be minimized.

As such, with the highly-efficient high-frequency amplifier device of this example, in the configuration of including the Doherty-type amplifier sections (Doherty-type amplifiers) 61 to 68, the line portion forming the input circuit 62 of the carrier amplifier 63 included in the Doherty-type amplifier sections 61 to 68 is configured by using a substrate material being physically stable against any change observed in the humidity, the temperature, and others.

### NINTH EXAMPLE

Described next is a highly-efficient high-frequency amplifier device in the ninth example of the present invention.

With the highly-efficient high-frequency amplifier device of this example, in the configuration of including a Doherty-type amplifier, a substrate material being physically stable against the humidity, the temperature, and others is used for a high-frequency line portion forming an output circuit of the carrier amplifier 63 that is one of the components of the Doherty-type amplifier. Here, used as the line forming the output circuit of the carrier amplifier 63 is an output path, e.g., the quarter wavelength line 64.

In the highly-efficient high-frequency amplifier device of this example, it is possible to reduce the degradation of the Doherty properties caused by any property change observed in the substrate material as a result of any change observed in the circumferential environment relating to the humidity, the temperature, and others. For example, the degradation of the properties can be minimized. More in detail, it is possible to prevent a problem of failing to achieve Doherty combination due to a phase change caused by degradation, by the humidity, the temperature, and others, of the substrate of the quarter wavelength line 64 in the stage subsequent to the carrier amplifier 63.

As such, with the highly-efficient high-frequency amplifier device of this example, in the configuration of including the Doherty-type amplifier sections (Doherty-type amplifiers) 61 to 68, the line portion forming the output circuit (the quarter wavelength line 64 in this example) of the carrier amplifier 63 in the Doherty-type amplifier sections 61 to 68 is configured by using a substrate material being physically stable against any change observed in the humidity, the temperature, and others.

### TENTH EXAMPLE

Described next is a highly-efficient high-frequency amplifier device in the tenth example of the present invention.

With the highly-efficient high-frequency amplifier device of this example, in the configuration of including a Doherty-type amplifier, a substrate material being physically stable against the humidity, the temperature, and others is used for a high-frequency line portion forming an input circuit of the peak amplifier 66 that is one of the components of the Doherty-type amplifier. Here, used as a line forming the input circuit of the peak amplifier 66 is an input path, e.g., the quarter wavelength line 65.

In the highly-efficient high-frequency amplifier device of this example, it is possible to reduce the degradation of the Doherty properties caused by any property change observed in the substrate material affected by the change of circumferential environment relating to the humidity, the temperature, and others. For example, the degradation of the properties can be minimized. More in detail, it is possible to prevent a problem of failing to achieve Doherty combination due to a phase change caused by degradation, by the humidity, the temperature, and others, of the substrate of the quarter wavelength line 65 in the stage preceding to the peak amplifier 66.

As such, with the highly-efficient high-frequency amplifier device of this example, in the configuration of including the Doherty-type amplifier sections (Doherty-type amplifiers) 61 to 68, the line portion forming the input circuit (the quarter wavelength line 65 in this example) of the peak amplifier 66 in the Doherty-type amplifier sections 61 to 68 is configured by using a substrate material being physically stable against any change observed in the humidity, the temperature, and others.

### ELEVENTH EXAMPLE

Described next is a highly-efficient high-frequency amplifier device in the eleventh example of the present invention.

With the highly-efficient high-frequency amplifier device of this example, in the configuration of including a Doherty-type amplifier, a substrate material being physically stable against the humidity, the temperature, and others is used for a high-frequency line portion forming a Doherty combination section that is one of the components of the Doherty-type amplifier. Here, used as a line forming the Doherty combination section is the combination circuit 68, for example.

Therefore, in the highly-efficient high-frequency amplifier device of this example, it is possible to reduce the degradation of the Doherty properties caused by any property change observed in the substrate material affected by the change of circumferential environment relating to the humidity, the temperature, and others. For example, the degradation of the characteristics can be minimized. More in detail, this enables to prevent a problem of failing to achieve Doherty combination due to a phase change caused by degradation, by the temperature or humidity, of the substrate of the Doherty combination section (the combination circuit 68 in this example).

As such, with the highly-efficient high-frequency amplifier device of this example, in the configuration of including the Doherty-type amplifier sections (Doherty-type amplifiers) 61 to 68, the line portion forming the Doherty combination section (the combination circuit 68 in this example) included in the Doherty-type amplifier sections 61 to 68 is configured by using a substrate material being physically stable against any change observed in the humidity, the temperature, and others.

Note that, with the highly-efficient high-frequency amplifier device of this example, in the configuration of including a Doherty-type amplifier, for example, one or more of the circuit portions, i.e., the power splitter circuit to the peak amplifier 66 and the carrier amplifier 63 both being the components of the Doherty-type amplifier (e.g., the power splitter 61), the input circuit 62 of the carrier amplifier 63, the output circuit of the carrier amplifier 63 (e.g., the quarter wavelength line 64), the input circuit of the peak amplifier 66 (e.g., the quarter wavelength line 65), the output circuit 67 of the peak amplifier 66, and the combination circuit 68 for a signal from the carrier amplifier 63 and a signal from the peak amplifier 66, can be configured using a substrate material physically stable against the humidity, the temperature, and others.

Therefore, in the highly-efficient high-frequency amplifier device of this example, it is possible to reduce the degradation of the Doherty properties caused by any property change observed in the substrate material affected by the change of circumferential environment relating to the humidity, the temperature, and others. For example, the degradation of the properties can be minimized.

Herein, the configuration of the amplifier of the present invention is not necessarily restrictive to those described above, and various other configurations will do.

### INDUSTRIAL APPLICABILITY

As described in the foregoing, according to the amplifier of the present invention, in the configuration of including a Doherty-type amplifier section (Doherty-type amplifier), the permittivity of a substrate configuring one or more quarter wavelength lines included in the Doherty-type amplifier section is increased compared with the permittivity of a substrate(s) in a close range. With such a configuration, the area occupied by the circuits can be reduced so that the device can be reduced in size.

Further, according to the amplifier of the present invention, in the configuration of including a Doherty-type amplifier section (Doherty-type amplifier), the permittivity of a substrate configuring the Doherty-type amplifier section is increased compared with the permittivity of a substrate(s) in a close range. With such a configuration, the area occupied by the circuits can be reduced so that the device can be reduced in size.

Still further, according to the amplifier of the present invention, in the configuration of including a Doherty-type amplifier section (Doherty-type amplifier), a line portion forming an output circuit of a carrier amplifier included in the Doherty-type amplifier section is configured by using a substrate material physically stable against any change observed in the humidity, the temperature. With such a configuration, the properties of the Doherty-type amplifier section (Doherty properties) can be stabilized against any environmental change of humidity or temperature, for example.

Still further, according to the amplifier of the present invention, in the configuration of including a Doherty-type amplifier section (Doherty-type amplifier), a line portion forming an input circuit of a peak amplifier included in the Doherty-type amplifier section is configured by using a substrate material physically stable against any change observed in the humidity, the temperature. With such a configuration, the properties of the Doherty-type amplifier section (Doherty properties) can be stabilized against any environmental change of humidity or temperature, for example.

Still further, according to the amplifier of the present invention, in the configuration of including a Doherty-type amplifier section (Doherty-type amplifier), a line portion forming a combination circuit included in the Doherty-type amplifier section is configured by using a substrate material physically stable against any change observed in the humidity and the temperature. With such a configuration, the properties of the Doherty-type amplifier section (Doherty properties) can be stabilized against any environmental change of humidity and temperature, for example.

Still further, according to the amplifier of the present invention, the permittivity of a substrate configuring partially or entirely the Doherty-type amplifier section is increased compared with the permittivity of a substrate(s) in a close range, and a line portion forming a part of the Doherty-type amplifier section is configured by using a substrate material physically stable against either or both of any change observed in the humidity, the temperature, and others. With such a configuration, the area occupied by the circuits of the amplifier can be reduced so that the device can be reduced in size, and the properties of the Doherty-type amplifier section (Doherty properties) can be stabilized against any environmental change of humidity or temperature, for example.

1. An amplifier configured by including a Doherty-type amplifier section, wherein
a permittivity of a substrate configuring partially or entirely the Doherty-type amplifier section is increased compared with a permittivity of a substrate in a close range, and
a line portion forming a part of the Doherty-type amplifier section is configured by using a substrate that is physically stable against either or both of any change observed in a humidity and a temperature.

2. An amplifier configured by including a Doherty-type amplifier section, wherein
a permittivity of a substrate configuring one or more of a quarter wavelength line included in the Doherty-type amplifier section is increased compared with a permittivity of a substrate in a close range.

3. An amplifier configured by including a Doherty-type amplifier section, wherein
a permittivity of a substrate configuring the Doherty-type amplifier section is increased compared with a permittivity of a substrate in a close range.

4. An amplifier configured by including a Doherty-type amplifier section, wherein
a line portion forming an output circuit of a carrier amplifier included in the Doherty-type amplifier section is configured by using a substrate material that is physically stable against either or both of any change observed in a humidity and a temperature.

5. An amplifier configured by including a Doherty-type amplifier section, wherein
a line portion forming an input circuit of a peak amplifier included in the Doherty-type amplifier section is configured by using a substrate material that is physically stable against either or both of any change observed in a humidity and a temperature.

6. An amplifier configured by including a Doherty-type amplifier section, wherein
a line portion forming a combination circuit that combines an output from a carrier amplifier included in the Doherty-type amplifier section with an output from a peak amplifier is configured by using a substrate material that is physically stable against either or both of any change observed in a humidity and a temperature.
